(19) United States
(12) Patent Application Publication
(10) Pub. No.: US 2020/0012188 A1
(43) Pub. Date: Jan. 9, 2020

(54) PHOTORESIST COMPOSITION FOR LINE DOUBLING

(71) Applicant: Applied Materials, Inc., Santa Clara, CA (US)

(72) Inventors: Ankit VORA, Bothell, WA (US); Christopher Dennis BENCHER, Cupertino, CA (US)

(21) Appl. No.: 16/502,918

(22) Filed: Jul. 3, 2019

Related U.S. Application Data
(60) Provisional application No. 62/695,549, filed on Jul. 9, 2018.

(51) Int. Cl. G03F 7/004; G03F 7/039

(52) U.S. Cl. CPC G03F 7/0045; G03F 7/162; G03F 7/0048; G03F 7/039

(57) ABSTRACT

Photoresist compositions, methods of manufacturing the photoresist compositions, and methods of using the photoresist compositions are provided. In one implementation, the photoresist composition comprises a novolac (novolac) resin, a diazonaphthoquinone (DNQ) dissolution inhibitor, a bis(azide) crosslinker, and a casting solvent. In one implementation, the bis(azide) crosslinker absorbs at wavelengths in a range between 325 nanometers and 400 nanometers. In one implementation, the bis(azide) crosslinker is an aromatic bi(azide) crosslinker.

### CROSS-REFERENCE TO RELATED APPLICATIONS

This application claims benefit of U.S. Provisional Patent Application Ser. No. 62/695,549, filed Jul. 9, 2018, which is incorporated herein by reference in its entirety.

### BACKGROUND

### Field

Aspects described herein generally relate to a photoresist composition. More particularly to a photoresist composition, methods of manufacturing the photoresist composition, and methods of using the photoresist composition.

### Description of the Related Art

Large area substrates are often utilized to support electrical features used in electronic devices. In some cases, large area substrates are used when manufacturing flat panels for active matrix displays such as computers, touch panel devices, personal digital assistances (PDAs), cell phones, television monitors, and the like. Generally, flat panels may comprise a layer of liquid crystal material forming pixels sandwiched between two plates. When power from the power supply is applied across the liquid crystal material during use, an amount of light passing through the liquid crystal material may be precisely controlled at pixel locations enabling images to be generated.

In some cases, microlithography techniques are employed to create electrical features incorporated as part of the liquid crystal material layer forming the pixels. According to this technique, a radiation-sensitive photoresist is applied to form a layer on a substrate surface with either a track or coater system to produce typically a sub-millimeter thickness of photoresist upon at least one surface of the substrate. Generally, in these techniques, a thin coating of a film of a photoresist composition is first applied to an underlying substrate material. The coated substrate is then baked to evaporate any solvent in the photoresist composition and to fix the radiation-sensitive photoresist coating onto the substrate. The baked-coated surface of the substrate is next subjected to an imagewise exposure to radiation.

This radiation exposure causes a chemical transformation in the exposed areas of the coated surface. After this imagewise exposure, the coated substrate is treated with a developer solution to dissolve and remove either the radiation-exposed (in the case of positive photoresist) or the unexposed (in the case of negative photoresist) areas of the coated surface of the substrate.

There are two types of photoresists in common use, positive photoresists and negative photoresists. Positive photoresists are sensitized when exposed to ultraviolet light so that exposed areas will dissolve in a developer solution leaving behind unexposed areas. Negative photoresists are hardened by exposure to ultraviolet light so exposed areas are inhibited from being dissolved by the developer solution while unexposed areas are dissolved.

Demand continues to increase for less expensive, larger, and higher performance electronic devices. Larger substrates with smaller and more uniform features are a prerequisite to satisfy the demand for these electronic devices. However, current approaches can be costly and time-consuming. Accordingly, new approaches are needed to more precisely create smaller and more uniform patterns on large substrates. Thus, there is a need for improved photoresist compositions and methods of using photoresists.

### SUMMARY

Aspects described herein generally relate to a photoresist composition. More particularly to a photoresist composition, methods of manufacturing the photoresist composition, and methods of using the photoresist composition. In at least one aspect, a photoresist composition is provided. The photoresist composition comprises a novolac (novolak) resin, a diazonaphthoquinone (DNQ) dissolution inhibitor, a bis(azide) crosslinker, and a casting solvent. In one implementation, the bis(azide) crosslinker absorbs at wavelengths in a range between 325nanometers and 400 nanometers. In at least one aspect, the bis(azide) crosslinker is an aromatic bis(azide) crosslinker.

In at least one aspect, a method of preparing a photoresist composition is provided. The method comprises providing a first proportion of a positive tone component. The positive tone component comprises a novolac resin and a diazonaphthoquinone (DNQ) type dissolution inhibitor. The method comprises providing a second proportion of a negative tone component. The negative tone component comprises a bis(azide) crosslinker. The method further comprises combining the first and second proportions in a mixture in amounts effective to cause the positive and negative tone components to respond together to a single exposure such that a first portion of the photoresist that is exposed to a first actinic energy level of the single exposure remains photoactive; a second portion of the photoresist that is exposed to a second actinic energy level of the single exposure becomes substantially photo-inactive; and a third portion of the photoresist that is exposed to an intermediate range of actinic energy levels between the first and second energy levels becomes soluble in developer solution.

In at least one aspect, a process for forming an image on a substrate is provided. The process comprises coating a substrate with a composition. The composition comprises a novolac resin, a diazonaphthoquinone (DNQ) dissolution inhibitor, a bis(azide) crosslinker, and a casting solvent. The process further comprises imagewise exposing through a mask with ultraviolet radiation. The method further comprises developing the exposed photoresist composition with a developer.

### BRIEF DESCRIPTION OF THE DRAWINGS

So that the manner in which the above-recited features of the present disclosure can be understood in detail, a more particular description of the implementations, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIGS. 1A-1G illustrate cross-sectional views of a structure at various stages of fabrication according to implementations described herein; and

FIG. 2 illustrates a process flow chart summarizing one implementation of a method of forming a structure using a photomask material according to implementations described herein.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

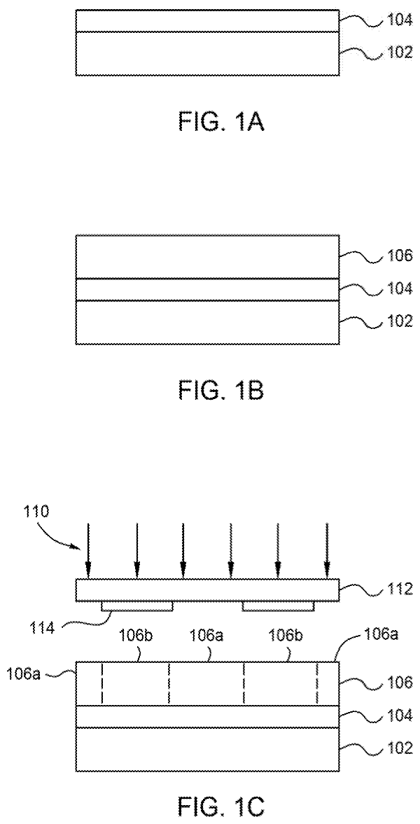

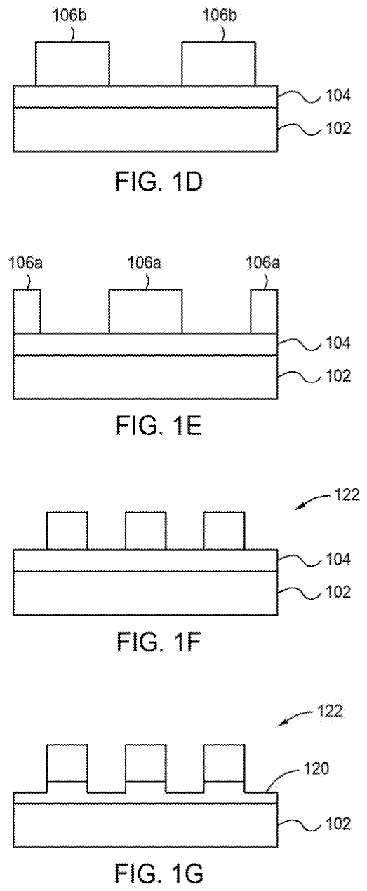

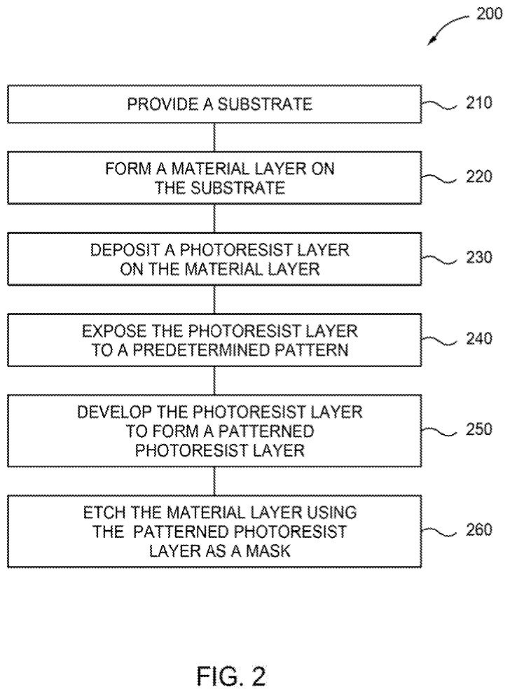

The following disclosure describes photoresist compositions and photolithography/microlithography techniques using the aforementioned photoresist compositions. Certain details are set forth in the following description and in FIGS. 1A-2 to provide a thorough understanding of various implementations of the disclosure. Other details describing well-known structures and systems often associated with microlithography techniques are not set forth in the following disclosure to avoid unnecessarily obscuring the description of the various implementations.

Many of the details, dimensions, angles and other features shown in the Figures are merely illustrative of particular implementations. Accordingly, other aspects can have other details, components, dimensions, angles and features without departing from the spirit or scope of the present disclosure. In addition, further aspects of the disclosure can be practiced without several of the details described below.

For large area substrates, the current state-of-the-art photoresist is a single tone novolac-DNQ-based resist. However, this current state-of -the-art resist cannot achieve the 50-nanometer line/space patterns currently targeted in the industry. Current state-of-the-art semiconductor resists can achieve 50-nanometer line/space patterns. However, these semiconductor resists involve a lower wavelength light source as well as a post exposure bake (PEB) process. Lower wavelength light sources and PEB processes are both expensive and not practical for large area substrates. Large area substrates are often glass substrates and it is undesirable to expose these large area glass substrates to the anneal temperatures, which are often part of a PEB process.

Aspects of the present disclosure provide a photoresist material having, simultaneously, both a positive tone and a negative tone response to exposure. The positive tone response dominates at the lower exposure dose while the negative response dominates at the higher exposure dosages. Exposure of this resist creates a space/line/space combination, whereas conventional resists produce only a single feature. The photoresist material described herein enables 50-nanometer line/space patterns that conventional resists are unable to achieve. In addition, the photoresist material described herein does not involve a PEB process.

For the frequency doubling photoresist material of the present disclosure, the positive tone response causes an increase in solubility in the areas where diffraction effects have reduced the exposure intensity, such as the areas near the edge of the reticle image. As the exposure dose is increased, the negative tone response predominates, causing a reduction in solubility in the more highly exposed areas. In this manner, the image is “frequency doubled” to produce twice the number of features than would otherwise be obtainable with the conventional photoresist.

The frequency doubling photoresist material is typically formulated using some components of existing positive and negative tone resists. This includes, for example, novolac resins, DNQ type inhibitors, bis(azide) cross-linkers, casting solvents and, optionally, a base additive and a photosensitizer.

The relative responses of the positive and negative tone functions of the frequency doubling photoresist material described herein can also be altered by modifying the exposure conditions. For example, the negative tone line of the hybrid resist does vary with exposure dose and reticle dimension, similar to the behavior of a conventional resist. Thus, as exposure dose is increased, for example, the negative tone line increases in width, and the spaces remain the same size, but the spaces are shifted to a new position on the substrate, since the spaces lie adjacent to the negative line. Similarly, the positive tone lines alter in size as the exposure dose or reticle dimension are altered.

As another example, two reticles could be used to print two separate patterns in the resist. One reticle could be exposed with a high dose, causing the hybrid functions to be expressed in the frequency doubling photoresist material. Another reticle could be exposed in the same resist film at a lower dose, causing only the positive tone function to be expressed in that portion of the photoresist material. This effect could also be accomplished with a single expose process if, for example, the reticle contained a partial filter of the actinic radiation in the areas where a lower exposure dose was targeted. This allows wider spaces to be printed at the same time as the narrower features, which is desirable in some device applications.

In a modification of this two-phase imaging approach, the frequency doubling photoresist material described herein can be used to create a standard negative tone pattern. If the photoresist material is imagewise exposed with a standard negative tone reticle and then blanket exposed with actinic radiation and developed, the result is a standard negative tone image. As an alternative to this method, the resist may be blanket exposed to a low dose of actinic energy after the imagewise exposure. The desirability of the method would depend on whether a solubility inhibiting protective group is present on the resin and whether the positive tone response is temperature dependent.

In at least one aspect, the frequency doubling photoresist material described herein is formed from a formulation comprising a positive, non-chemically amplified photoresist that does not involve a post-exposure-bake (PEB) process and a bis(azide) compound that can crosslink with the components of the positive, non-chemically amplified resist forming a negative image when exposed to light having a wavelength, for example, in a range from 325 to 400 nanometers.

In at least one aspect, the frequency doubling photoresist material described herein is formed by providing a first proportion of a positive tone component and providing a second proportion of a negative tone component. The positive tone component includes a novolac resin and a diazonaphthoquinone (DNQ) type dissolution inhibitor. The negative tone component comprises a bis(azide) crosslinker. The first and second proportions are combined in a mixture in amounts effective to cause the positive and negative tone components to respond together to a single exposure such that a first portion of the photoresist that is exposed to a first actinic energy level of the single exposure remains photoactive; a second portion of the photoresist that is exposed to a second actinic energy level of the single exposure becomes substantially photo-inactive; and a third portion of the photoresist that is exposed to an intermediate range of actinic energy levels between the first and second levels becomes soluble in developer solution.

In at least one aspect, a reaction system for preparation of a frequency doubling photoresist layer as described herein is provided. The reaction system comprises (a) a novolac resin, (b) a DNQ-type dissolution inhibiter, (c) a bis(azide) crosslinker, and (d) a casting solvent. In at least one aspect, the reaction system further comprises (e) a base additive. In at least one aspect, the reaction system further comprises (f) a sensitizer.

Component (a) includes a phenol-formaldehyde resin such as a novolac resin. In at least one aspect, the novolac-based resin is prepared by polycondensation of phenol-based and aldehyde-based compounds. The phenol-based compound can use at least one selected from the group of phenol, m-cresol, and p-cresol, etc. The aldehyde-based compound can use formaldehyde, benzaldehyde, acetaldehyde, etc. The condensation reaction of phenol-based and aldehyde-based compounds can use a general acidic catalyst. In at least one aspect, the novolac resin has an average molecular weight from about 1,000 to about 30,000.

In at least one aspect, the novolac resin is prepared by subjecting a phenol or a substituted phenol to an addition-condensation reaction of a phenol or substituted phenol (or a combination thereof) and an aldehyde or ketone (or a combination thereof), in the presence of an acid or a divalent metal salt catalyst, in a suitable reaction solvent, as are well known to one skilled in the art of photoresists. Suitable phenols include, but are not limited to, phenol, chlorophenols, fluorophenols, m-cresol, o-cresol, p-cresol, m-ethyl phenol, o-ethyl phenol, p-ethyl phenol, m-butyl phenol, o-butyl phenol, p-butyl phenol, trimethylsilylphenol, chloromethylphenol 2,3-xylenol, 2,4-xylenol, 2,5-xylenol, 2,6-xylenol, 3,4-xylenol, 3,5-xylenol, 3,6-xylenol, o-phenyl phenol, m-phenyl phenol, p-phenyl phenol, 2,3,5-trimethylphenol, 2,3,5-triethylphenol, 3,4,5-trimethylphenol, 4-tert-butylphenol, 3-tert-butylphenol, 2-tert-butylphenol, 2-tert-butyl-4-methylphenol, 2-tert-butyl-5-methylphenol and other alkyl-substituted phenols; p-methoxyphenol, m-methoxyphenol, o-methoxyphenol, p-ethoxyphenol, m-ethoxyphenol, o-ethoxyphenol, o-propoxyphenol, p-propoxyphenol, propoxyphenol and other alkoxy-substituted phenols; o-isopropenylphenol, p-isopropenylphenol, 2-methyl-4-isopropenylphenol, 2-ethyl-4-isopropenylphenol and other isopropenyl-substituted phenols: 2-phenylphenol and other aryl-substituted phenols; 4,4′-dihydroxybiphenyl, bisphenol A, hydroquinone, resorcinol, 2-methyl resorcinol, 5-methyl resorcinol, pyrogallol, catechol, and other polyhydroxyphenols, as are well known to those skilled in the photoresist art. These phenols may be used either alone or in an admixture of two or more, depending upon the dissolution rate targeted.

Examples of the aldehyde, that may be used, either alone or in combination, include formaldehyde, paraformaldehyde, acetaldehyde, benzaldehyde, furfural, trioxane, propionaldehyde, butylaldehyde, trimethylacetaldehyde, acrolein (acrylaldehyde), crotonaldehyde, cyclohexanaldehyde, furylacrolein, terephthalaldehyde, phenylacetaldehyde, alpha-phenylpropylaldehyde, beta-phenylpropylaldehyde, o-hydroxybenzaldehyde, m-hydroxybenzaldehyde, p-hydroxybenzaldehyde, o-methylbenzaldehyde, m-methylbenzaldehyde, p-methylbenzaldehyde, o-chlorobenzaldehyde, m-chlorobenzaldehyde, p-chlorobenzaldehyde, and cinnamaldehyde, and the like.

Examples of the ketones include acetone, methyl ethyl ketone, diethyl ketone, and diphenyl ketone. Each of these ketones may be used singly or in combination. Further, an optional combination of any of aldehydes and any of ketones can be employed.

Examples of the acid catalyst that may be utilized include inorganic acids such as hydrochloric acid, nitric acid, sulfuric acid and the like, organic acids such as formic acid, oxalic acid, maleic acid and the like, and divalent inorganic metal salts of copper, cobalt, magnesium, manganese, nickel, zinc and the like. The reaction solvent is normally a hydrophilic solvent, such as methanol or dioxane. Preferred alkali-soluble, film forming novolac resins include phenol-formaldehyde novolac(s), cresol-formaldehyde novolac(s), and phenol-modified xylenol-formaldehyde novolac(s).

Component (b) includes diazonaphthoquinone (“DNQ”) or a DNQ derivative. The DNQ functions as a dissolution inhibitor.

Component (c) includes a bis(azide) crosslinker. Any suitable bis(azide) crosslinker may be used. In at least one aspect, the bis(azide) crosslinker absorbs at wavelengths in a range between 325 nanometers and 400 nanometers. Examples of bis(azide) crosslinkers include aromatic bis(azides). Examples of aromatic bis(azides) include, but are not limited to, p-phenylenebisazide, 4,4′-diazidobiphenyl, 4,4′-diazido-3,3′-dimethylbiphenyl, 4,4′-diazidobiphenylmethane, 3,3′-dichloro-4,4′-diazidobiphenylmethane, 4,4′-diazidobiphenyl ether, 4,4′-diazidobiphenyl sulfide, 4,4′-diazidobiphenyl disulfide, 4,4′-diazidobiphenyl sulfone, 3,3′-diszidobiphenyl sulfone, 4,4′-diazidobenzophenone, 4,4′-diazidobenzyl, 4,4′-diazidostilbene, 4,4′-diazidochalcone, 2,6-bis(4-azidobenzylidene)cyclohexanone, 2,6-bis(4-azidobenzylidene)-4-methylcyclohexanone, 2,7-diazidofluorene, or a combination thereof.

Component (d) includes a casting solvent. The casting solvent is used to provide proper consistency to the entire composition so that it may be applied to the substrate surface without the layer being too thick or too thin. Any suitable casting solvent may be used. Examples of casting solvents include, but are not limited to, cyclohexanone, acetone, ethyl lactate, NMP (1-methyl-2-pyrrolidinone), diethyleneglycol dimethyl ether (diglyme), heptanone, propylene glycol methyl ether acetate (PGMEA), propylene glycol methyl ether (PGME), or a combination thereof.

Component (e) includes a base additive. Any suitable base additive may be used. Examples of base additives include, but are not limited to, dimethylamino pyridine, 7-diethylamino-4-methylcoumarin, tertiary amines, proton sponge, berberine, and the polymeric amines as in the “Pluronic” or “Tetronic” series from BASF. Additionally, tetra alkyl ammonium hydroxides or cetyltrimethylammonium hydroxide, may be used when the PAG is an onium salt.

Component (f) includes a sensitizer. Any suitable sensitizer may be used. Examples of suitable sensitizers include, but are not limited to, chrysenes, pyrenes, fluoranthenes, anthrones, benzophenones, thioxanthones, and anthracenes, such as 9-anthracene methanol (9-AM). The sensitizer may include oxygen or sulfur. The preferred sensitizers will be nitrogen free, because the presence of nitrogen, e.g., an amine or phenothiazine group, tends to sequester the free acid generated during the exposure process and the formulation will lose photosensitivity.

FIGS. 1A-1G illustrate cross-sectional views of a structure at various stages of fabrication according to implementations described herein. FIG. 2 illustrates a process flow chart summarizing one aspect of a processing sequence 200 of forming a structure using a photomask material according to implementations described herein. The processing sequence 200 described in FIG. 2 corresponds to the fabrication stages depicted in FIGS. 1A-1G, which are discussed below.

The processing sequence 200 begins at operation 210 by providing a substrate 102. In at least one aspect, the substrate 102 is a large area substrate for use in the fabrication of liquid crystal displays (LCD's), flat panel displays, organic light emitting diodes (OLED's), or photovoltaic cells for solar cell arrays. In at least one aspect, the substrate 102 may be a thin sheet of metal, plastic, organic material, silicon, glass, quartz, or polymer, among others suitable materials. In at least one aspect, the substrate 102 has a surface area greater than about one square meter, such as greater than about two square meters.

In at least one aspect, the substrate 102 is made of silicon or other semiconductor materials. Alternatively or additionally, the substrate 102 includes other elementary semiconductor materials such as germanium. In at least one aspect, the substrate 102 is made of a compound semiconductor such as silicon carbide, gallium arsenic, indium arsenide, or indium phosphide. In at least one aspect, the substrate 102 is made of an alloy semiconductor such as silicon germanium, silicon germanium carbide, gallium arsenic phosphide, or gallium indium phosphide.

At operation 220, a material layer 104 is formed on the substrate 102. The material layer 104 is designed to form specific patterns. In at least one aspect, the material layer 104 is a dielectric layer. In at least one aspect, the material layer is a high-k dielectric layer. In at least one aspect, the high-k dielectric material is selected from zirconium oxide (ZrO₂), hafnium oxide (HfO₂), aluminum oxide (Al₂O₃), and combinations thereof. In at least one aspect, the material layer 104 is a metal layer. In at least one aspect, the high-k dielectric material is doped. In at least one aspect, the doped high-k dielectric material is an aluminum-doped zirconium oxide containing material.

At operation 230, after forming the material layer 104, a photoresist layer 106 is formed on the material layer 104, as shown in FIG. 1C, in accordance with some aspects of the present disclosure. In at least one aspect, the photoresist layer 106 is a frequency doubling photoresist layer formed from the photoresist compositions described herein. In at least one aspect, deposition of the photoresist layer 106 includes photoresist coating (e.g., spin-on coating), soft baking, mask aligning, exposure, developing the photoresist, rinsing, drying (e.g., hard baking), or other suitable processes.

At operation 240, the photoresist layer 106 is exposed to a predetermined pattern. Referring to FIG. 1C, after the photoresist layer 106 is formed on the material layer 104, the photoresist layer 106 is exposed to a radiation beam 110 shown through a mask 112. In at least one aspect, the mask 112 includes blocking portions 114 that do not allow the radiation beam 110 to pass through. The pattern of the mask 112 is transferred to the photoresist layer 106. Therefore, the photoresist layer 106 is patterned and includes an exposed regions 106a and unexposed regions 106b.

In at least one aspect, the radiation beam 110 is an ultra-violet (UV) or extreme ultra-violet (EUV) laser. In at least one aspect, the laser has a wavelength in a range from 325 nm to 400 nm, such as a 397 nm beam from an excimer laser, a 395 nm beam from an excimer laser, a 375 nm beam from an excimer laser, a 360 nm beam from an excimer laser, a 355 nm beam from an excimer laser, a 351 nm beam from an excimer laser, or a 349 nm beam from an excimer laser.

After the photoresist layer 106 is exposed by the radiation beam 110, the photoresist layer 106 is baked by heat in accordance with some aspects of the present disclosure. The function of baking is to decompose the photoreactive polymer in the photoresist layer 106 and to evaporate solvent. In at least one aspect, after the radiation beam 110 exposes the photoresist layer 106, the photoresist layer 106 is baked by heat in accordance with some aspects of the disclosure. The function of baking is to decompose the photoreactive polymer in the photoresist layer 106 and to evaporate solvent.

At operation 250, the photoresist layer is developed to form a patterned resist layer. In at least one aspect, the photoresist layer 106 is exposed to a developer solution as shown in accordance with some aspects of the disclosure. In at least one aspect, the developer solution is an aqueous solution. In at least one aspect, the developer solution is tetramethylammonium hydroxide (TMAH) solution. In at least one aspect, the developer solution is a sodium hydroxide (NaOH) solution. In at least one aspect, the exposure time of the photoresist layer 106 to the developer solution is dependent on the composition of the developer solution.

FIG. 1D illustrates a cross-sectional view of a structure where the developed photoresist layer 106 is a positive resist. In the positive resist, the initially unexposed regions 106b of the photoresist layer 106 is insoluble in developer, while the exposed resist becomes more soluble as the exposure dose is increased above a threshold value. FIG. 1 E illustrates a cross-sectional view of a structure where the developed photoresist layer 106 is a negative resist. In the negative resist, the initially unexposed regions 106b of the photoresist layer 106 are soluble in developer, while the exposed regions 106a of the resist are relatively insoluble. The positive resist of FIG. 1D and the negative resist of FIG. 1 E are provided to illustrate the differences between a positive resist, a negative resist, and the frequency doubling resist depicted in FIG. 1F.

FIG. 1F illustrates a cross-sectional view of a structure where the developed photoresist layer 106 is a frequency doubling resist 122 having both a positive tone and a negative tone response to exposure according to aspects of the present disclosure. The positive tone response dominates at the lower exposure dose while the negative response predominates at the higher exposure dosages. Exposure of this hybrid resist creates a space/line/space combination, whereas either of the conventional resists would produce only a single feature.

At operation 260, the material layer 104 is etched using the patterned photoresist layer 106 as a mask to form the patterned material layer 120 as shown in FIG. 1G. The material layer may be etched using known etching chemistries.

Aspects:

Clause 1. A photoresist composition, comprising a novolac resin, a diazonaphthoquinone (DNQ) dissolution inhibitor, a bis(azide) crosslinker, and a casting solvent.

Clause 2. The photoresist composition of clause 1, wherein the bis(azide) crosslinker absorbs at wavelengths in a range between 325 nanometers and 400 nanometers.

Clause 3. The photoresist composition of clause 1 or 2, wherein the bis(azide) crosslinker is an aromatic bi(azide) crosslinker.

Clause 4. The photoresist composition of any of clauses 1 to 3, wherein the aromatic bi(azide) crosslinker is selected from p-phenylenebisazide, 4,4′-diazidobiphenyl, 4,4′-diazido-3,3′-dimethylbiphenyl, 4,4′-diazidobiphenylmethane, 3,3′-dichloro-4,4′-diazidobiphenylmethane, 4,4′-diazidobiphenyl ether, 4,4′-diazidobiphenyl sulfide, 4,4′-diazidobiphenyl disulfide, 4,4′-diazidobiphenyl sulfone, 3,3′-diszidobiphenyl sulfone, 4,4′-diazidobenzophenone, 4,4′-diazidobenzyl, 4,4′-diazidostilbene, 4,4′-diazidochalcone, 2,6-bis(4-azidobenzylidene)cyclohexanone, 2,6-bis(4-azidobenzylidene)-4-methylcyclohexanone, 2,7-diazidofluorene, or a combination thereof.

Clause 5. The photoresist composition of any of clauses 1 to 4, wherein the casting solvent is selected from cyclohexanone, acetone, ethyl lactate, NMP (1-methyl-2-pyrrolidinone), diethyleneglycol dimethyl ether (diglyme), heptanone, propylene glycol methyl ether acetate (PGMEA), propylene glycol methyl ether (PGME), or a combination thereof.

Clause 6. The photoresist composition of any of clauses 1 to 5 further comprising a sensitizer selected from chrysene, pyrenes, fluoranthenes, anthrones, benzophenones, thioxanthones, anthracenes, or a combination thereof.

Clause 7. A method of preparing a photoresist composition, comprising providing a first proportion of a positive tone component comprising a phenolic novolac resin and a diazonaphthoquinone (DNQ) type dissolution inhibitor, providing a second proportion of a negative tone component comprising a bis(azide) crosslinker, combining the first and second proportions in a mixture in amounts effective to cause the positive and negative tone components to respond together to a single exposure such that a first portion of the photoresist that is exposed to a first actinic energy level of the single exposure remains photoactive, a second portion of the photoresist that is exposed to a second actinic energy level of the single exposure becomes substantially photo-inactive; and a third portion of the photoresist that is exposed to an intermediate range of actinic energy levels between the first and second actinic energy levels becomes soluble in developer solution.

Clause 8. The method of clause 7, wherein the first actinic energy level is lower than the second actinic energy level.

Clause 9. The method of clause 7 or 8, wherein the second actinic energy level is lower than the first actinic energy level.

Clause 10. The method of any of clauses 7 to 9, wherein the first portion of the photoresist that is exposed to the first actinic energy level of the single exposure additionally remains insoluble in developer.

Clause 11. The method of any of clauses 7 to 10, wherein the second portion of the photoresist that is exposed to the second actinic energy level of the single exposure additionally becomes insoluble in developer.

Clause 12. The method of any of clauses 7 to 11, wherein the third portion of the photoresist that is exposed to the intermediate range of actinic energy levels between the first and second actinic energy levels additionally remains photoactive.

Clause 13. The method of any of clauses 7 to 12, wherein the first actinic energy level of exposure comprises approximately zero exposure and wherein the second actinic energy level of exposure comprises a full exposure.

Clause 14. The method of any of clauses 7 to 13, wherein the bis(azide) crosslinker absorbs at wavelengths in a range between 325 nanometers and 400 nanometers.

Clause 15. The method of any of clauses 7 to 14, wherein the bis(azide) crosslinker is an aromatic bi(azide) crosslinker.

Clause 16. The method of any of clauses 7 to 15, wherein the aromatic bi(azide) crosslinker is selected from p-phenylenebisazide, 4,4′-diazidobiphenyl, 4,4′-diazido-3,3′-dimethylbiphenyl, 4,4′-diazidobiphenylmethane, 3,3′-dichloro-4,4′-diazidobiphenylmethane, 4,4′-diazidobiphenyl ether, 4,4′-diazidobiphenyl sulfide, 4,4′-diazidobiphenyl disulfide, 4,4′-diazidobiphenyl sulfone, 3,3′-diszidobiphenyl sulfone, 4,4′-diazidobenzophenone, 4,4′-diazidobenzyl, 4,4′-diazidostilbene, 4,4′-diazidochalcone, 2,6-bis(4-azidobenzylidene)cyclohexanone, 2,6-bis(4-azidobenzylidene)-4-methylcyclohexanone, 2,7-diazidofluorene, or a combination thereof.

Clause 17. A method for forming an image on a substrate, comprising coating a substrate with a photoresist composition, comprising a novolac resin, a diazonaphthoquinone (DNQ) dissolution inhibitor, a bis(azide) crosslinker, and a casting solvent, imagewise exposing the photoresist composition through a mask with ultraviolet radiation, and developing the exposed photoresist composition with a developer.

Clause 18. The method of clause 17, wherein the substrate is a sheet of metal, plastic, organic material, silicon, glass, quartz, or polymer.

Clause 19. The method of clause 17 or 18, wherein the substrate is a large area substrate having a surface area greater than 1 meter.

Clause 20. The method of any of clauses 17 to 19, wherein the ultraviolet radiation has a wavelength in a range from 325 nm to 400 nm.

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

1. A photoresist composition, comprising:
a novolac resin;
a diazonaphthoquinone (DNQ) dissolution inhibitor;
a bis(azide) crosslinker; and
a casting solvent.

2. The photoresist composition of claim 1, wherein the bis(azide) crosslinker absorbs at wavelengths in a range between 325 nanometers and 400 nanometers.

3. The photoresist composition of claim 1, wherein the bis(azide) crosslinker is an aromatic bi(azide) crosslinker.

4. The photoresist composition of claim 3, wherein the aromatic bi(azide) crosslinker is selected from p-phenylenebisazide, 4,4′-diazidobiphenyl, 4,4′-diazido-3,3′-dimethylbiphenyl, 4,4′-diazidobiphenylmethane, 3,3′-dichloro-4,4′-diazidobiphenylmethane, 4,4′-diazidobiphenyl ether, 4,4′-diazidobiphenyl sulfide, 4,4′-diazidobiphenyl disulfide, 4,4′-diazidobiphenyl sulfone, 3,3′-diszidobiphenyl sulfone, 4,4′-diazidobenzophenone, 4,4′-diazidobenzyl, 4,4′-diazidostilbene, 4,4′-diazidochalcone, 2,6-bis(4-azidobenzylidene)cyclohexanone, 2,6-bis(4-azidobenzylidene)-4-methylcyclohexanone, 2,7-diazidofluorene, or a combination thereof.

5. The photoresist composition of claim 1, wherein the casting solvent is selected from cyclohexanone, acetone, ethyl lactate, NMP (1-methyl-2-pyrrolidinone), diethyleneglycol dimethyl ether (diglyme), heptanone, propylene glycol methyl ether acetate (PGMEA), propylene glycol methyl ether (PGME), or a combination thereof.

6. The photoresist composition of claim 1 further comprising:
a sensitizer selected from chrysenes, pyrenes, fluoranthenes, anthrones, benzophenones, thioxanthones, anthracenes, or a combination thereof.

7. A method of preparing a photoresist composition, comprising:
providing a first proportion of a positive tone component comprising:
a phenolic novolac resin; and
a diazonaphthoquinone (DNQ) type dissolution inhibitor;
providing a second proportion of a negative tone component comprising:
a bis(azide) crosslinker;
combining the first and second proportions in a mixture in amounts effective to cause the positive and negative tone components to respond together to a single exposure such that:
a first portion of the photoresist that is exposed to a first actinic energy level of the single exposure remains photoactive;
a second portion of the photoresist that is exposed to a second actinic energy level of the single exposure becomes substantially photo-inactive; and
a third portion of the photoresist that is exposed to an intermediate range of actinic energy levels between the first and second actinic energy levels becomes soluble in developer solution.

8. The method of claim 7, wherein the first actinic energy level is lower than the second actinic energy level.

9. The method of claim 7, wherein the second actinic energy level is lower than the first actinic energy level.

10. The method of claim 7, wherein the first portion of the photoresist that is exposed to the first actinic energy level of the single exposure additionally remains insoluble in developer.

11. The method of claim 7, wherein the second portion of the photoresist that is exposed to the second actinic energy level of the single exposure additionally becomes insoluble in developer.

12. The method of claim 7, wherein the third portion of the photoresist that is exposed to the intermediate range of actinic energy levels between the first and second actinic energy levels additionally remains photoactive.

13. The method of claim 7, wherein the first actinic energy level of exposure comprises approximately zero exposure and wherein the second actinic energy level of exposure comprises a full exposure.

14. The method of claim 7, wherein the bis(azide) crosslinker absorbs at wavelengths in a range between 325 nanometers and 400 nanometers.

15. The method of claim 7, wherein the bis(azide) crosslinker is an aromatic bi(azide) crosslinker.

16. The method of claim 15, wherein the aromatic bi(azide) crosslinker is selected from p-phenylenebisazide, 4,4′-diazidobiphenyl, 4,4′-diazido-3,3′-dimethylbiphenyl, 4,4′-diazidobiphenylmethane, 3,3′-dichloro-4,4′-diazidobiphenylmethane, 4,4′-diazidobiphenyl ether, 4,4′-diazidobiphenyl sulfide, 4,4′-diazidobiphenyl disulfide, 4,4′-diazidobiphenyl sulfone, 3,3′-diszidobiphenyl sulfone, 4,4′-diazidobenzophenone, 4,4′-diazidobenzyl, 4,4′-diazidostilbene, 4,4′-diazidochalcone, 2,6-bis(4-azidobenzylidene)cyclohexanone, 2,6-bis(4-azidobenzylidene)-4-methylcyclohexanone, 2,7-diazidofluorene, or a combination thereof.

17. A method for forming an image on a substrate, comprising:
coating a substrate with a photoresist composition, comprising:
a novolac resin; a diazonaphthoquinone (DNQ) dissolution inhibitor;
a bis(azide) crosslinker; and
a casting solvent;
imagewise exposing the photoresist composition through a mask with ultraviolet radiation; and
developing the exposed photoresist composition with a developer.

18. The method of claim 17, wherein the substrate is a sheet of metal, plastic, organic material, silicon, glass, quartz, or polymer.

19. The method of claim 18, wherein the substrate is a large area substrate having a surface area greater than 1 meter.

20. The method of claim 17, wherein the ultraviolet radiation has a wavelength in a range from 325 nm to 400 nm.
